(19) United States
(12) Patent Application Publication
(10) Pub. No.: US 2008/0145996 A1
(43) Pub. Date: Jun. 19, 2008

(54) Method for Manufacturing Dielectric Thin Film Capacitor

(76) Inventors: Masanobu Nomura, Yasu-shi (JP); Yutaka Takeshima, Nagaokakyo-shi (JP); Toshio Hagi, Otsu-shi (JP); Naotoshi Nakagawa, Rittou-shi (JP)

Correspondence Address: DICKSTEIN SHAPIRO LLP, 1177 AVENUE OF THE AMERICAS (6TH AVENUE), NEW YORK, NY, 10036-2714, US

(21) Appl. No.: 11/954,696

(22) Filed: Dec. 12, 2007

(30) Foreign Application Priority Data
Dec. 19, 2006 (JP) 2006-341098

(51) Int. Cl. H01L 21/02

(52) U.S. Cl. 438/396; 257/E21.011

(57) ABSTRACT

A method for manufacturing a dielectric thin film capacitor without causing cracks in a protective layer which covers a capacitor portion is provided. The method for manufacturing the dielectric thin film capacitor includes a step of forming a tapered resist pattern on a capacitor structure and a dry etching step so as to taper the end portion of the capacitor. Furthermore, a heating treatment is conducted after tapering.

### BACKGROUND OF THE INVENTION

1. Field of the Invention

The present invention relates to a method for manufacturing a dielectric thin film capacitor.

2. Description of the Related Art

Recently, dielectric thin film capacitors manufactured by “thin film technologies” including a metal organic decomposition (MOD) method, a sol-gel method, and a sputtering method have been studied. Such dielectric thin film capacitors have a structure in which an upper electrode and a lower electrode hold a dielectric layer formed by the thin film technology therebetween.

Furthermore, in order to improve characteristics such as the reliability and the moisture resistance of the dielectric thin film capacitors, protective layers composed of organic and inorganic materials may be formed.

Japanese Unexamined Patent Application Publication No. 2004-327867 discloses a thin film capacitor including electrode layers with different polarities. At least one of the electrode layers has a stepped end portion in which the thickness decreases toward the peripheral end in order to prevent stress from being concentrated at the end portion when the stepped portion possessed by the electrode layer is covered with a dielectric thin film and a protective layer. Thus, the stepped portion can prevent cracks from occurring in the thin dielectric film and the protective layer.

In the thin film capacitor described in the above-mentioned document, the electrode layer has the stepped portion in which the thickness of the stepped portion decreases toward the peripheral end thereof. Therefore, since the stress that is concentrated at the end portion of the electrode layer is relaxed, cracks and the like little occur in the dielectric thin film and the protective layer.

The thickness of the stepped portion described in the above-mentioned document decreases toward the peripheral of the electrode layer. Although the thickness becomes small, the stepped portion is still present as compared with the case of no stepped portion. Therefore, in the case of using a silicon nitride layer having low strength as the protective layer, cracks may still occur in the protective layer.

Furthermore, in order to form such a stepped portion, photolithography must be performed repeatedly (see, for example, paragraph [0042] of Japanese Unexamined Patent Application Publication No. 2004-327867). This leads to complication of the manufacturing process, resulting in an increase of the manufacturing cost.

Furthermore, a resist residue remains on the upper electrode layer after the photolithographic process including forming a resist pattern and dry etching. The upper electrode layer is usually formed by forming the resist pattern, and then dry etching to partially remove the upper electrode layer for ensuring high processing accuracy.

For example, when the upper electrode layer is patterned by ion-milling, since ions collide with the entirety of the substrate on which the dielectric layer and the upper electrode layer are disposed, heat is generated by collision of the ions to cure the resist pattern. This causes a difficulty in removing the resist pattern, thereby easily causing residue.

Oxygen plasma treatment is a well-known method for removing the resist residue. The resist pattern cured by the heat, which is caused by ion-milling as mentioned above, needs a highly energized plasma treatment must to be completely removed. This, however, may damage the upper electrode layer and the dielectric layer.

On the other hand, if the energy of the oxygen plasma treatment is sufficiently low so as not to damage the upper electrode and the dielectric layer, it is difficult to completely remove the resist residue. In such a case, the protective layer cannot function satisfactorily since the resist residue remains between the upper electrode layer and the protective layer. In an experiment performed by the inventors of the present invention, when a capacitor in which a protective layer of silicon nitride was disposed on an upper electrode layer having resist residue thereon was subjected to a moisture resistance test, water entered a boundary between the upper electrode layer and the protective layer and characteristics of the capacitor were significantly deteriorated.

Accordingly, it is an object of the present invention to provide a method for manufacturing a dielectric thin film capacitor capable of simply manufacturing a dielectric thin film capacitor without causing cracks in a protective layer covering a capacitor portion.

Furthermore, it is another object of the present invention to provide a method for manufacturing a dielectric thin film capacitor wherein little resist residue remains after photolithographic patterning of an upper electrode.

### SUMMARY OF THE INVENTION

As a result of intensive research to achieve the objects, the inventors of the present invention found that if an end portion of a capacitor structure in which a lower electrode, a dielectric layer, and an upper electrode are stacked in that order is tapered, stress can be prevented from being concentrated at the end portion of the capacitor structure and cracks can be prevented from occurring in a protective layer.

Furthermore, the inventors found that the side face of the capacitor structure can be easily tapered by dry etching using a tapered resist pattern formed on the capacitor structure.

Furthermore, the inventors found a problem in that leak current which flows between the upper electrode and the lower electrode is increased because electrical insulation of the end surface of the dielectric layer treated by dry etching is lowered by damage by the dry etching. However, it was found that heat treatment after the dry etching can solve the problem.

The present invention is based on the above-mentioned findings. A method for manufacturing a dielectric thin film capacitor of the preferred embodiments of the present invention includes the steps of depositing a lower electrode, a dielectric layer, and an upper electrode on a substrate in that order to form a capacitor structure in which the dielectric layer is held between the lower electrode and the upper electrode; forming a resist pattern on the capacitor structure; removing parts of the capacitor structure by dry etching using the resist pattern as a mask; heating the capacitor structure in an oxidative atmosphere after the removal of the resist pattern; and forming a protective layer covering at least a part of the capacitor structure. In the method, at least a part of the side face of the resist pattern is inclined from the edge to the center of the resist pattern in a direction away from the surface in contact with the capacitor structure, and the step of removing a part of the capacitor structure includes removing a part of the capacitor structure so that at least a part of the side face of the capacitor structure is inclined from the edge of the capacitor structure to the center of the capacitor structure in a direction away from the surface in contact with the substrate.

The protective layer is preferably composed of silicon nitride.

Furthermore, in the dry etching step of removing a part of the capacitor structure, the upper electrode and the dielectric layer may be removed in one operation.

According to a preferred embodiment of the present invention, at least a portion of the side face of a capacitor structure can be tapered by dry etching using as a mask a resist pattern in which at least a portion of the side is tapered, i.e., the side face of the resist pattern is inclined from the edge to the center of the capacitor structure away from the bottom (the surface in contact with the capacitor structure) to the top surface of the resist pattern.

Therefore, cracks in a protective layer can be prevented from occurring by concentration of stress at the end portion of the capacitor structure. Also, since there is no need to repeat photolithography for forming a step portion, unlike in existing methods, the manufacturing process can be simplified and the production cost can be lowered.

Furthermore, according to a preferred embodiment of the present invention, since heat treatment is performed after tapering of the capacitor structure, resist pattern residue remaining on the upper surface of the capacitor structure can be securely removed by thermal decomposition.

Furthermore, since the heat treatment is performed after tapering of the capacitor structure, leak current can be reduced.

A mechanism for reducing the leak current by heat treatment will be described in detail. Leak current between the upper electrode and the lower electrode varies according to the creeping distance of the dielectric layer for insulating between the upper electrode and the lower electrode and the electric insulation of the surface of the dielectric layer. When the heat treatment is performed, the edge of the upper electrode contracts so as to expose a portion of the surface of the dielectric layer, which is not damaged by dry etching, and the creeping distance between the upper electrode and the lower electrode is increased thereby reducing the leak current.

When the heat treatment is performed after patterning of the capacitor structure, residue of the resist pattern used in patterning is thermally decomposed. Therefore, since little resist residue remains on the upper electrode, adhesiveness between the upper electrode and the protective layer is improved, so that the protective layer can function satisfactorily. Other features, elements, characteristics and advantages of the present invention will become more apparent from the following detailed description of preferred embodiments of the present invention with reference to the attached drawings.

### BRIEF DESCRIPTION OF THE DRAWINGS

FIGS. 1A to 1E are cross-sectional views showing respective steps for manufacturing a dielectric thin film capacitor according to EXAMPLE 1 of the present invention;

FIGS. 2F to 2I are cross-sectional views showing respective steps for manufacturing the dielectric thin film capacitor according to EXAMPLE 1 of the present invention;

FIGS. 3J to 3L are cross-sectional views showing respective steps for manufacturing the dielectric thin film capacitor according to EXAMPLE 1 of the present invention;

FIGS. 4A to 4E are cross-sectional views showing respective steps for manufacturing a dielectric thin film capacitor according to EXAMPLE 2 of the present invention;

FIGS. 5F to 5H are cross-sectional views showing respective steps for manufacturing the dielectric thin film capacitor according to EXAMPLE 2 of the present invention;

FIGS. 6I to 6K are cross-sectional views showing respective steps for manufacturing the dielectric thin film capacitor according to EXAMPLE 2 of the present invention;

FIGS. 7A and 7B are partial cross-sectional views showing a main part of a dielectric thin film capacitor according to an embodiment of the present invention;

FIGS. 8A to 8D are cross-sectional views showing respective steps for manufacturing a dielectric thin film capacitor according to EXAMPLE 3 of the present invention;

FIGS. 9E to 9G are cross-sectional views showing respective steps for manufacturing the dielectric thin film capacitor according to EXAMPLE 3 of the present invention;

FIGS. 10A to 10D are cross-sectional views showing respective steps for manufacturing a dielectric thin film capacitor according to EXAMPLE 4 of the present invention;

FIGS. 11E to 11H are cross-sectional views showing respective steps for manufacturing the dielectric thin film capacitor according to EXAMPLE 4 of the present invention; and

FIG. 12 is a cross-sectional view showing a modified example of the dielectric thin film capacitor according to EXAMPLE 4 of the present invention.

### DESCRIPTION OF THE PREFERRED EMBODIMENTS

### First Embodiment

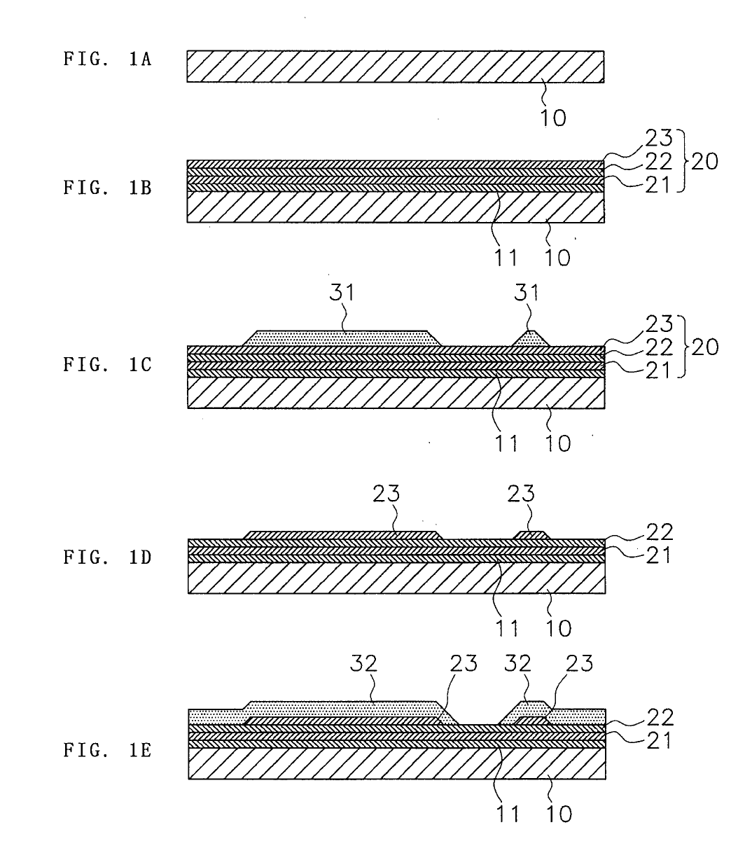

A preferred embodiment of the present invention will be described below with reference to the drawings. FIGS. 1A to 3L are cross-sectional views showing respective steps for manufacturing a dielectric thin film capacitor according to a first embodiment of the present invention.

As shown in FIG. 1A, a substrate 10 is prepared and an adhesive layer 11, a lower electrode 21, a dielectric layer 22, and an upper electrode 23 are stacked in that order on the substrate 10 as shown in FIG. 1B. A silicon substrate, a sapphire substrate, a quartz substrate, or the like can be used as the substrate 10. The adhesive layer 11 is deposited to improve the adhesion between the substrate 10 and the lower electrode 21. TiO₂ or Al₂O₃ can be preferably used as a material of the adhesive layer 11. A layer of dielectric material having the same composition as the dielectric layer 22 can also be preferably used as the adhesive layer 11.

The lower electrode 21 and the upper electrode 23 are preferably formed using a material which is resistant to oxidization because these electrodes are exposed to an oxidative atmosphere at a high temperature during the formation of the dielectric layer 22. Therefore, noble metals such as Pt or electrically conductive oxides such as Ir₂O₃ are preferably used.

A metal oxide with a high dielectric constant having a perovskite structure, a bismuth layer structure, or a tungsten bronze structure is used for the dielectric layer 22. Specifically, (Ba,St)TiO₃, Pb(Zr,Ti)O₃, SrBi₂Nb₂O₉, (Ba,Sr)Nb₂O₆, and PbNb₂O₆ can be used. The dielectric layer 22 can be formed by a metal organic decomposition method (MOD), a sol-gel method, a chemical vapor deposition method (CVD), or a sputtering method.

A capacitor structure 20 has the lower electrode 21, the upper electrode 23, and the dielectric layer 22 that is held between the lower electrode 21 and the upper electrode 23 in the thickness direction.

Next, a tapered resist pattern 31 is formed on the upper electrode 23 as shown in FIG. 1C. The tapered resist pattern 31 can be formed by applying a resist, exposing the resist to light, and developing the resist, heating the resist at a predetermined temperature. That is, the resist is fluidized by heat treatment and formed into the tapered resist pattern 31 shown in FIG. 1C due to surface tension acting between the resist and the upper electrode 23.

Next, a part of the upper electrode 23 is removed as shown in FIG. 1D by ion-milling using the tapered resist pattern 31 as a mask. Since the tapered resist pattern 31 has a tapered shape, the etched surface of the upper electrode 23 also has a tapered shape. Next, the tapered resist pattern 31 is removed by oxygen plasma ashing. Note that the energy of the oxygen plasma ashing should be low so as not to damage the dielectric layer 22, even though this may result in some residue of the tapered resist pattern 31 remaining on the dielectric layer 22.

Then, a tapered resist pattern 32 shown in FIG. 1E is formed by the same method as used for forming the tapered resist pattern 31.

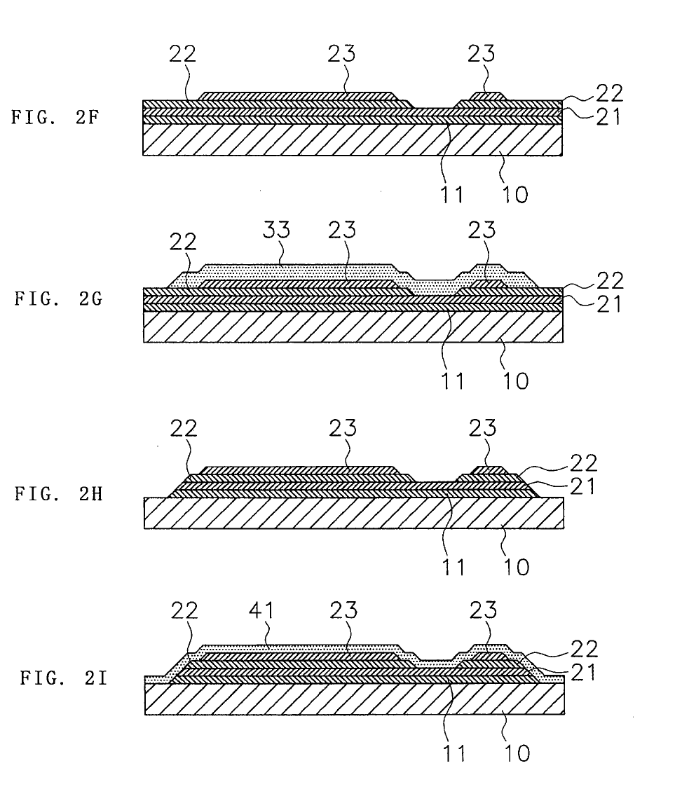

Next, a part of the dielectric layer 22 is removed as shown in FIG. 2F by ion-milling using the tapered resist pattern 32 as a mask. Then, the tapered resist pattern 32 is removed by oxygen plasma ashing. Note that the energy of the oxygen plasma ashing should be low so as not to damage the dielectric layer 22 and the lower electrode 21.

Next, a tapered resist pattern 33 shown in FIG. 2G, is formed by the same method as used for forming the tapered resist pattern 31 and the tapered resist pattern 32.

Next, parts of the adhesive layer 11, the lower electrode 21, and the dielectric layer 22 are removed in one operation by ion-milling using the tapered resist pattern 33 as a mask. Then, the tapered resist pattern 33 is removed by oxygen plasma ashing. Note that the energy of the oxygen plasma ashing is low so as not to damage the dielectric layer 22 and the substrate 10.

As a result, the adhesive layer 11, the lower electrode 21, and the dielectric layer 22 are tapered as shown in FIG. 2H. Each of etched surfaces of the adhesive layer 11, the lower electrode 21, and the dielectric layer 22 is inclined to the central portion in a direction away from the substrate 10.

Next, heat treatment is performed at a temperature of about 800° C., for example. By this heat treatment, the dielectric constant of the dielectric layer 22 is improved because the crystallinity of the dielectric layer 22 is improved, and the residue of the tapered resist pattern 32 is removed by thermal decomposition.

The heat treatment temperature is preferably 600° C. or higher. The reasons for this are that the crystallinity of the dielectric layer 22 can be sufficiently improved and the residue of the tapered resist pattern 32 is thermally decomposed sufficiently.

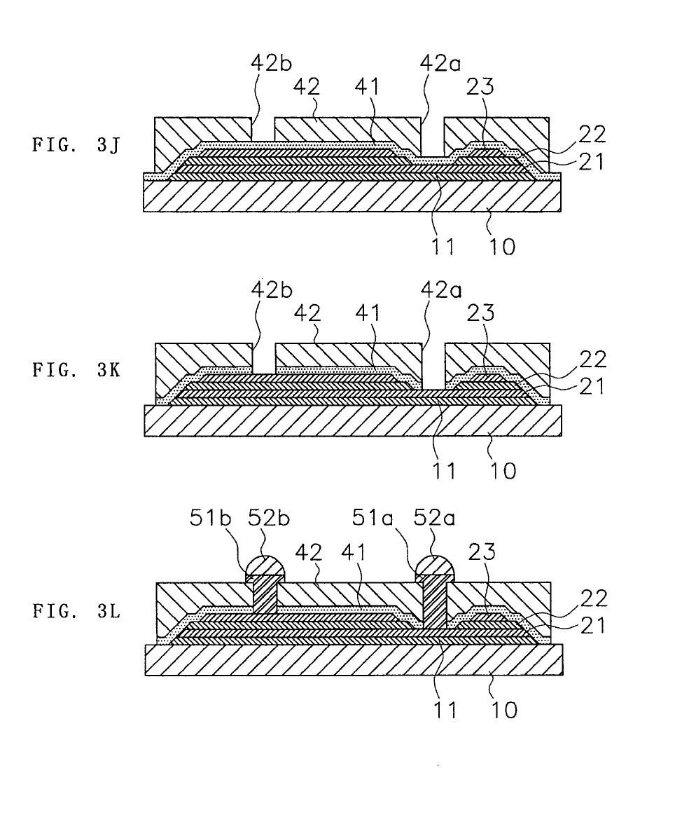

Next, a silicon nitride layer is deposited by sputtering or the like so as to form an inorganic protective layer 41 composed of silicon nitride as shown in FIG. 2I. Then an organic protective layer 42 made of photosensitive polyimide resin is formed as shown in FIG. 3J. In the organic protective layer 42, openings 42a and 42b are provided.

Next, as shown in FIG. 3K, the inorganic protective layer 41 is removed by reactive ion etching using the organic protective layer 42 as a mask. Consequently, the lower electrode 21 and the upper electrode 23 are exposed at the bottoms of the openings 42a and 42b, respectively.

Next, a metal layer of a metal such as Ni, Cu, or Au is disposed so as to cover the organic protective layer 42. Then, unnecessary portions of the metal layer are removed by photolithography in order to form lead conductors 51a and 51b in the openings 42a and 42b, respectively. As shown in FIG. 3L, the lead conductors 51a and 51b are connected to the lower electrode 21 and the upper electrode 23, respectively. Finally, solder bumps 52a and 52b are formed on the lead conductors 51a and 51b, respectively. The dielectric thin film capacitor of the present embodiment of the invention is manufactured in this manner.

The dielectric thin film capacitor mentioned above has substantially no step portion at the end portion of the capacitor structure. Therefore, since defects such as cracks do not easily occur in the inorganic protective layer 41 composed of silicon nitride, the dielectric thin film capacitor has high moisture resistance. Furthermore, since the residue of the resist pattern is removed by heat treatment after patterning of the capacitor structure by photolithography, residue of the resist pattern does not remain on the upper electrode even if the energy of oxygen plasma ashing is low so as to not to damage the dielectric layer.

### Second Embodiment

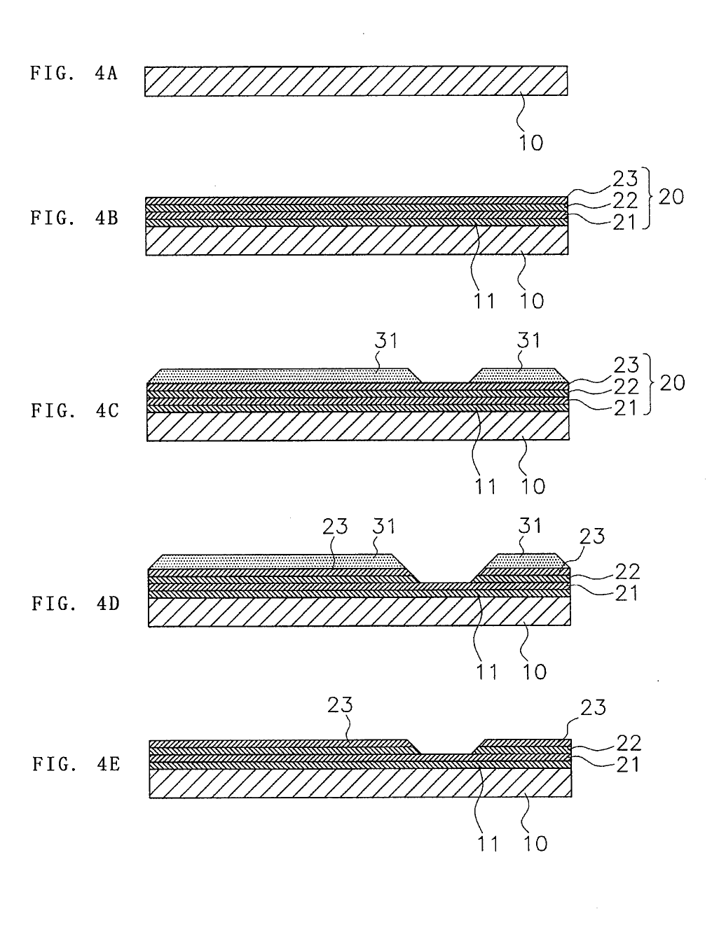

A preferred second embodiment of the present invention will be described below with reference to the drawings. FIGS. 4A to 6K are cross-sectional views showing respective steps for manufacturing a dielectric thin film capacitor according to a second embodiment of the present invention. Note that in FIGS. 4A to 6K, the same reference numerals will be used to denote common or similar components to those shown in FIGS. 1A to 3L, and redundant description is avoided.

As shown in FIG. 4A, a substrate 10 is provided and an adhesive layer 11, a lower electrode 21, a dielectric layer 22, and an upper electrode 23 are stacked in that order on the substrate 10 as shown in FIG. 4B. A capacitor structure 20 includes the lower electrode 21, the upper electrode 23, and the dielectric layer 22 that is held between the lower electrode 21 and the upper electrode 23 in the thickness direction.

Next, a tapered resist pattern 31 is formed on the upper electrode 23 as shown in FIG. 4C. A resist is applied on the upper electrode 23 and then exposed to light and developed. After the development, heat treatment is performed to form the tapered resist pattern 31. That is, the resist is fluidized by heat treatment and takes the form of the tapered resist pattern 31 shown in FIG. 4C due to surface tension between the resist and the upper electrode 23.

Next, as shown in FIG. 4D, parts of layers including the upper electrode 23 and the dielectric layer 22 are removed in one operation by ion-milling using the tapered resist pattern 31 as a mask. Since the tapered resist pattern 31 has a tapered shape, etched surfaces of the upper electrode 23 and the dielectric layer 22 are formed to also have a tapered shape.

Next, the tapered resist pattern 31 is removed by oxygen plasma ashing as shown in FIG. 4E.

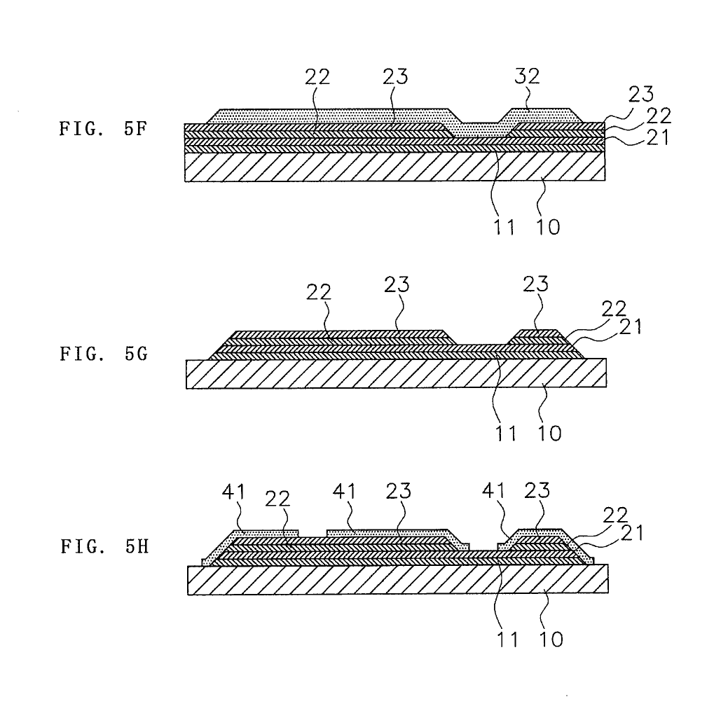

Then, a tapered resist pattern 32 shown in FIG. 5F is formed using the same method as used for forming the tapered resist pattern 31.

Next, parts of layers including the adhesive layer 11, the lower electrode 21, the dielectric layer 22, and the upper electrode 23 are removed in one operation by ion-milling using the tapered resist pattern 32 as a mask. Then, the tapered resist pattern 32 is removed by oxygen plasma ashing. By the above-mentioned processes, as shown in FIG. 5G, the adhesive layer 11, the lower electrode 21, the dielectric layer 22, and the upper electrode 23 are formed into a tapered shape. Each of the etched surfaces of the adhesive layer 11, the lower electrode 21, the dielectric layer 22, and the upper electrode 23 is inclined toward the central portion of the etched layer.

Next, heat treatment is performed at a temperature of about 800° C., for example. By this heat treatment, the dielectric constant of the dielectric layer 22 is improved because the crystallinity of the dielectric layer 22 is improved, and the residues of the resist patterns 31 and 32 are removed by thermal decomposition. When the heat treatment is performed, the leak current that flows between the upper electrode 23 and the lower electrode 21 can be reduced because the edge of the upper electrode 23 contracts.

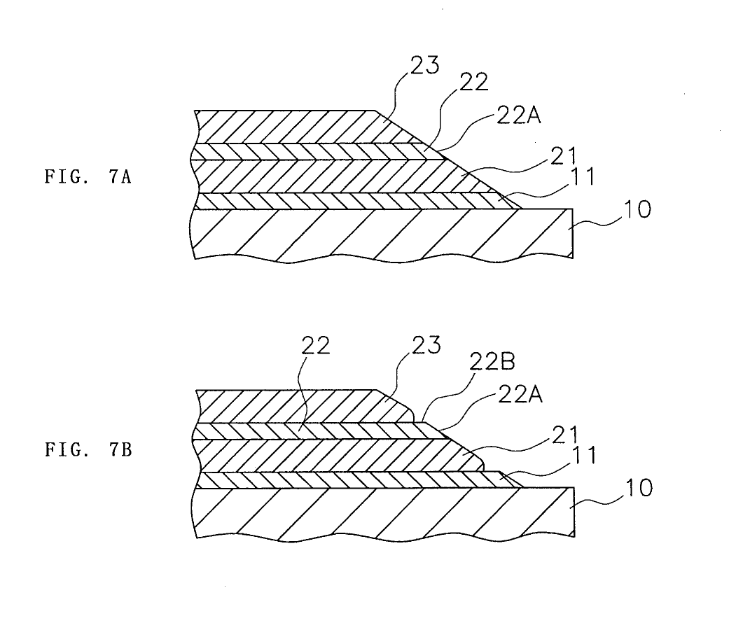

A mechanism for reducing the leak current between the upper electrode 23 and the lower electrode 21 by heat treatment will be described in detail. FIG. 7A shows the end surfaces of the lower electrode 21, the dielectric layer 22, and upper electrode 23 after ion-milling. Since the etched surface 22A of the dielectric layer 22 is damaged by ion-milling, electrical insulation provided by the surface of the dielectric layer 22 is lowered and the leak current flows easily. Furthermore, since the viscosity provided by a metal material of the upper electrode 23 is lowered by the heat treatment, the end portion of the upper electrode 23 contracts so as to reduce the surface area thereof. As a result, the end portion of the upper electrode 23 is rounded on the side in contact with the dielectric layer 22 as shown in FIG. 7B. By this phenomenon, since the upper surface 22B, which is not damaged by ion-milling, of the dielectric layer 22 is exposed, the leak current is reduced. Furthermore, since the creeping distance of the dielectric layer 22 between the upper electrode 23 and the lower electrode 21 is increased as a result of the exposure of the upper surface 22B, the leak current is also reduced.

The heating temperature is preferably 600° C. or higher. The reasons for this are that the crystallinity of the dielectric layer 22 can be sufficiently improved, the residue of the tapered resist pattern 32 is thermally decomposed sufficiently, and the viscosity of the end portion of the upper electrode 23 is sufficiently lowered in the above-mentioned temperature range.

Note that, in the first embodiment, after the heat treatment, the leak current is also reduced by the same mechanism as mentioned above. In the first embodiment, however, since the etched surface of the upper electrode 23 does not continue from etched surfaces of the dielectric layer 22 and the lower electrode 21, the creeping distance between the electrodes is basically larger than the creeping distance set in the second embodiment. Therefore, in the case that the layers including the upper electrode 23, the dielectric layer 22, and the lower electrode 21 are etched in one operation as described in the second embodiment, the effect of reducing the leak current by the above-mentioned mechanism is significantly exhibited.

Next, a silicon nitride layer is deposited by sputtering or the like. Then, the silicon nitride layer is patterned by photolithography into an inorganic protective layer 41 shown in FIG. 5H. In the inorganic protective layer 41, openings are provided so as to expose parts of the upper electrode 23 and the lower electrode 21.

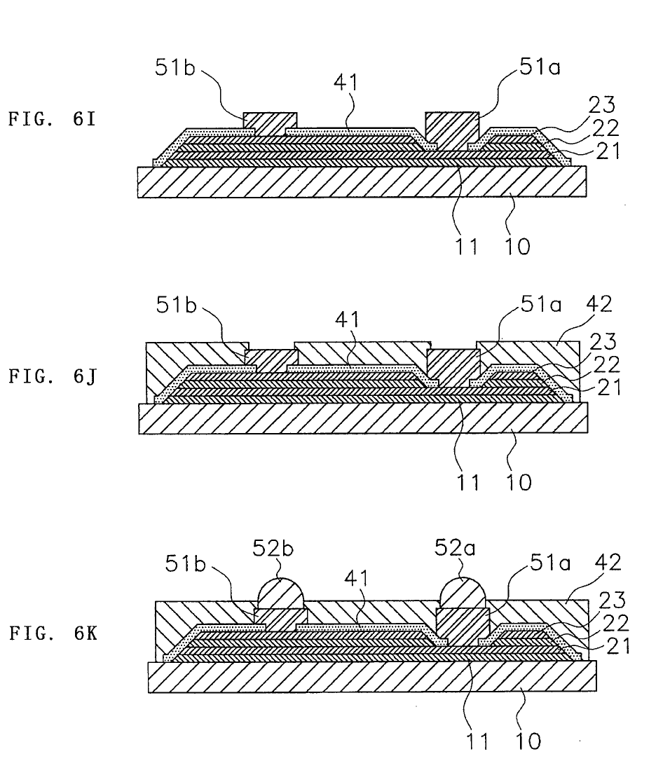

As shown in FIG. 6I, a metal film is formed by a proper method and patterned by photolithography so as to form lead conductors 51a and 51b that are connected to the lower electrode 21 and the upper electrode 23, respectively, via the openings provided in the inorganic protective layer 41. Metals such as Cu, Ni, and Au can be used for the material of the lead conductors 51a and 51b. The lead conductors 51a and 51b may also have a multilayered structure. In order to improve adhesion between the upper electrode 23 and the lower electrode 21, a Ti layer can be deposited therebetween.

Then, an organic protective layer 42 made of photosensitive polyimide resin is formed as shown in FIG. 6J. In the organic protective layer 42, openings are provided to expose the top surfaces of the lead conductors 51a and 51b at the respective openings.

Next, solder bumps 52a and 52b are formed on the lead conductors 51a and 51b, respectively. The dielectric thin film capacitor of the present embodiment of the invention is manufactured in this manner.

The dielectric thin film capacitor mentioned above has substantially no step portion at the end portion of the capacitor structure. Therefore, since defects such as cracks do not easily occur in the inorganic protective layer 41 of silicon nitride, the dielectric thin film capacitor has high moisture resistance. Furthermore, since the residue of the resist pattern is removed by heat treatment after patterning of the capacitor structure using photolithography, residue of the resist pattern does not remain on the upper electrode even if the energy of the oxygen plasma ashing is low so as not to damage the dielectric layer. Furthermore, the heat treatment after the formation of the upper electrode 23 allows the upper electrode 23 to have a rounded shape at the end portion thereof as shown in FIG. 7B. Therefore, since the upper surface 22b of the dielectric layer 22 is exposed at the end portion of the capacitor structure, the effect of reducing the leak current is exhibited.

### Example 1

Next, EXAMPLE 1 of the present invention will be described more specifically with reference to FIGS. 1A to 3L.

As shown in FIG. 1A, a silicon substrate 10 having a thermally-oxidized film on the surface thereof (not shown) was prepared. Then, as shown in FIG. 1B, an adhesive layer 11, a lower electrode 21, a dielectric layer 22, and an upper electrode 23 were deposited in that order on the substrate 10.

The adhesive layer 11 was composed of Ba_{0.7}Sr_{0.3}TiO₃. An MOD material solution including Ba, Sr, and Ti (at a molar ratio of 7:3:10) was prepared and applied on the substrate 10 by spin coating and then dried. Next, the resulting dried layer had a thickness of about 100 nm after rapid thermal annealing (RTA) for about 30 minutes at a temperature of about 600° C. in an oxidative atmosphere.

The lower electrode 21 was made of a Pt film having a thickness of about 200 nm that was deposited on the adhesive layer 11 by sputtering.

The dielectric layer 22 was composed of Ba_{0.7}Sr_{0.3}TiO₃. An MOD material solution including Ba, Sr, and Ti (at a molar ratio of 7:3:10) was prepared and applied on the lower electrode 21 by spin coating and then dried. Next, the resulting dried layer had a thickness of about 100 nm after RTA for about 30 minutes at a temperature of about 650° C. in an oxidative atmosphere.

The upper electrode 23 was made of a Pt film having a thickness of about 200 nm that was deposited on the dielectric layer 22 by sputtering.

Next, a photosensitive resist was applied on the upper electrode 23 and then exposed to light and developed. After the development, heat treatment was performed at a temperature of about 250° C. to form a tapered resist pattern 31 shown in FIG. 1C. Further, parts of the upper electrode 23 were removed, as shown in FIG. 1D, by ion-milling using the tapered resist pattern 31 as a mask. Since the tapered resist pattern 31 was formed to have a tapered shape, an etched surface of the upper electrode 23 was also formed to have a tapered shape.

Next, the tapered resist pattern 31 was removed by oxygen plasma ashing, and a tapered resist pattern 32 shown in FIG. 1E was formed using the same method as used for forming the tapered resist pattern 31.

Next, parts of the dielectric layer 22 were removed as shown in FIG. 2F by ion-milling using the tapered resist pattern 32 as a mask. Then, the tapered resist pattern 32 was removed by oxygen plasma ashing.

Next, using the same method as used for forming the resist patterns 31 or 32, a tapered resist pattern 33 was formed as shown in FIG. 2G. Parts of layers including the dielectric layer 22, the lower electrode 21, and the adhesive layer 11 were removed in one operation by ion-milling as shown in FIG. 2H. The tapered resist pattern 33 was removed by oxygen plasma ashing.

Next, heat treatment was performed for about 30 minutes at a temperature of about 850° C. in an oxidative atmosphere. By this heat treatment, the dielectric constant of the dielectric layer 22 was improved because the crystallinity of the dielectric layer 22 was improved, and the residues of the resist patterns 31, 32, and 33 were removed by thermal decomposition.

Next, a silicon nitride film having a thickness of about 500 nm was deposited by sputtering to form an inorganic protective layer 41 as shown in FIG. 2I. Further, photosensitive polyimide resin was applied to a thickness of about 3 μm and cured at a temperature of about 300° C. to form an organic protective layer 42 as shown in FIG. 3J. In the organic protective layer 42, openings 42a and 42b were provided.

Next, parts of the inorganic protective layer 41 were removed by reactive ion etching using the organic protective layer 42 as a mask as shown in FIG. 3K. By this etching, the lower electrode 21 and the upper electrode 23 were exposed at the bottoms of the openings 42a and 42b, respectively.

Next, a Ti layer having a thickness of about 50 nm was deposited as an adhesive layer (not shown) by sputtering. Then, a Ni layer having a thickness of about 2000 nm and a Au layer having a thickness of about 100 nm were deposited in that order by sputtering. The two layers including the Ni layer and the Au layer were patterned by photolithography to form lead conductors 51a and 51b which were connected to the lower electrode 21 and the upper electrode 23, respectively, as shown in FIG. 3L. Then, Sn—Ag—Cu solder paste was applied by a printing method and a reflow process was performed at a temperature of about 240° C. to form solder bumps 52a and 52b on the lead conductors 51a and 51b, respectively, and complete a dielectric thin film capacitor.

### Example 2

Next, EXAMPLE 2 of the present invention will be described more specifically with reference to FIGS. 4A to 6K. Note that, for common part described in EXAMPLE 1, redundant description is avoided.

As shown in FIG. 4A, a substrate 10 was prepared and an adhesive layer 11, a lower electrode 21, a dielectric layer 22, and an upper electrode 23 were deposited on the substrate 10 in that order as shown in FIG. 4B.

Next, a photosensitive resist was applied on the upper electrode 23 and baked, and then exposed to light and developed. After the development, heat treatment was performed at a temperature of about 250° C. to form a tapered resist pattern 31 shown in FIG. 4C. Further, parts of the upper electrode 23 and the dielectric layer 22 were removed in one operation, as shown in FIG. 4D, by ion-milling using the tapered resist pattern 31 as a mask. Since the tapered resist pattern 31 was formed to have a tapered shape, etched surfaces including the surfaces of the upper electrode 23 and the dielectric layer 22 were also formed to have a tapered shape.

Next, the tapered resist pattern 31 was removed by oxygen plasma ashing, as shown in FIG. 4E, and then a tapered resist pattern 32 shown in FIG. 5F was formed by the same method as used for forming the tapered resist pattern 31.

Next, parts of the adhesive layer 11, the lower electrode 21, the dielectric layer 22, and the upper electrode 23 were removed in one operation by ion-milling using a tapered resist pattern 32 as a mask. Then, the tapered resist pattern 32 was removed by oxygen plasma ashing. Consequently, as shown in FIG. 5G, the adhesive layer 11, the lower electrode 21, the dielectric layer 22, and the upper electrode 23 were formed into a tapered shape. That is, each of the etched surfaces of the adhesive layer 11, the lower electrode 21, the dielectric layer 22, and the upper electrode 23 was inclined to the central portion in a direction away from the substrate 10.

Next, heat treatment was performed for about 30 minutes at a temperature of about 850° C. in an oxidative atmosphere. By this heat treatment, the dielectric constant of the dielectric layer 22 was improved because the crystallinity of the dielectric layer 22 was improved, and the residue of the resist patterns 32 was removed by thermal decomposition. Further, by this heat treatment, the leak current flowing between the upper electrode 23 and the lower electrode 21 was reduced because the edge of the upper electrode 23 contracted.

Next, a silicon nitride layer having a thickness of about 500 nm was deposited by sputtering. Then, openings were provided to expose parts of the upper electrode 23 and the lower electrode 21 by photolithography to form an inorganic protective layer 41 composed of silicon nitride as shown in FIG. 5H.

Next, a Ti layer having a thickness of about 50 nm was deposited as an adhesive layer (not shown) by sputtering. Then, a Ni layer having a thickness of about 2000 nm and a Au layer having a thickness of about 100 nm were deposited by sputtering. The two layers including the Ni layer and the Au layer were patterned by photolithography to form lead conductors 51a and 51b which were connected to the lower electrode 21 and the upper electrode 23, respectively, via the openings provided in the inorganic protective layer 41 as shown in FIG. 6I.

Next, photosensitive polyimide resin was applied and cured at a temperature of about 300° C. to form an organic protective layer 42 having an opening in which the upper surface of the lead conductors 51a or 51b was exposed as shown in FIG. 6J. The thickness of the organic protective layer 42 was about 2.5 μm.

Then, Sn—Ag—Cu solder paste was applied by a printing method and reflowed at a temperature of about 240° C. to form solder bumps 52a and 52b on the lead conductors 51a and 51b, respectively, and complete a dielectric thin film capacitor.

### Example 3

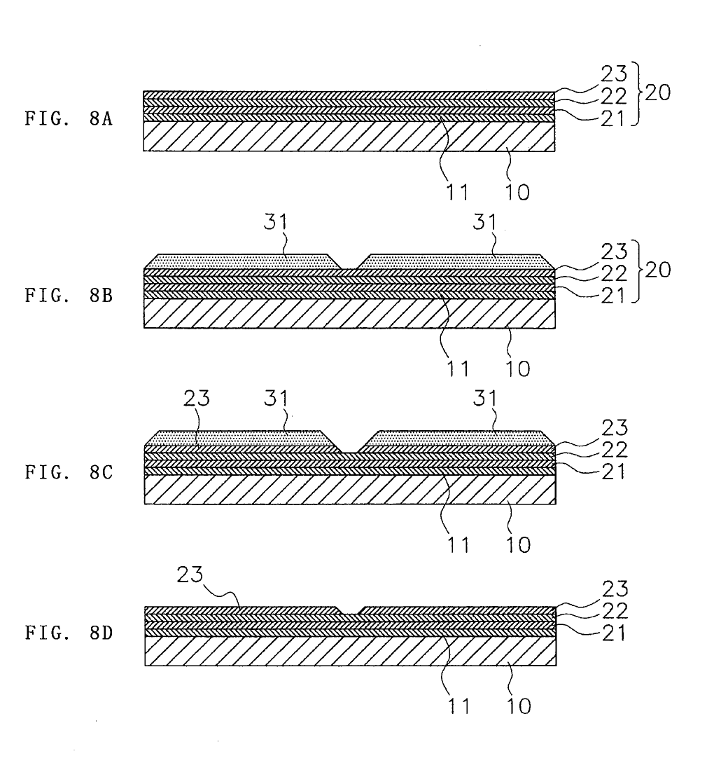

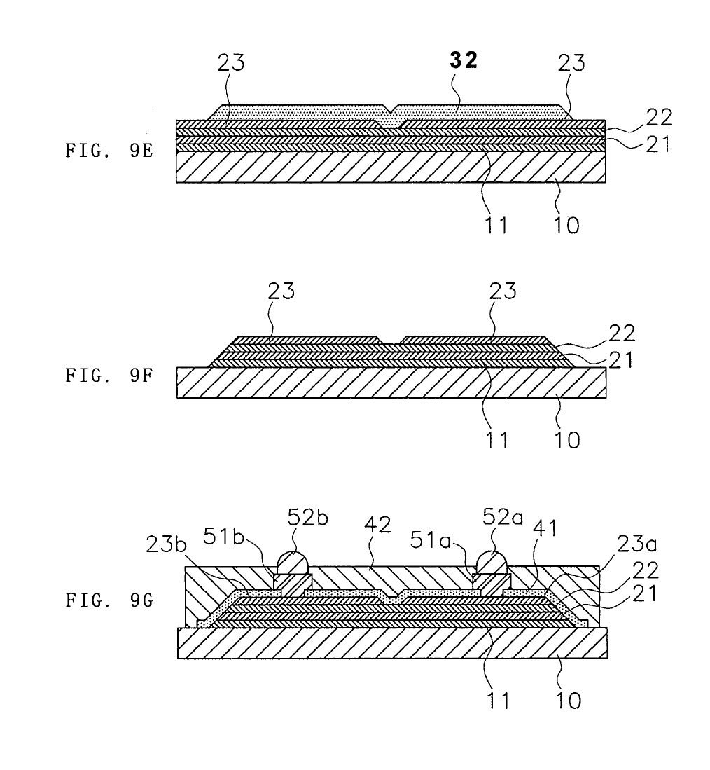

Next, EXAMPLE 3 of the present invention will be described with reference to FIGS. 8A to 9G. Note that, for common part described in EXAMPLE 1 and EXAMPLE 2, redundant description is avoided.

As shown in FIG. 8A, an adhesive layer 11, a lower electrode 21, a dielectric layer 22, and an upper electrode 23 were deposited on a substrate 10 using the same method as used in EXAMPLE 1.

Next, a tapered resist pattern 31 shown in FIG. 8B was formed on the upper electrode 23. Further, parts of the upper electrode 23 were removed as shown in FIG. 8C, by ion-milling using the tapered resist pattern 31 as a mask so as to divide the upper electrode 23 into two parts. Since the tapered resist pattern 31 was formed to have a tapered shape, an etched surface of the upper electrode 23 was also formed to have a tapered shape.

Next, the tapered resist pattern 31 was removed by oxygen plasma ashing, as shown in FIG. 8D, and then a tapered resist pattern 32 shown in FIG. 9E was formed using the same method as used for forming the tapered resist pattern 31.

Next, parts of the adhesive layer 11, the lower electrode 21, the dielectric layer 22, and the upper electrode 23 were removed in one operation by ion-milling using a tapered resist pattern 32 as a mask. Then, the tapered resist pattern 32 was removed by oxygen plasma ashing. Consequently, as shown in FIG. 9F, the adhesive layer 11, the lower electrode 21, the dielectric layer 22, and the upper electrode 23 were formed into a tapered shape. That is, the etched surfaces of the adhesive layer 11, the lower electrode 21, the dielectric layer 22, and the upper electrode 23 were inclined to the central portion in a direction away from the substrate 10.

Next, heat treatment was performed for about 30 minutes at a temperature of about 850° C. in an oxidative atmosphere. By this heat treatment, the dielectric constant of the dielectric layer 22 was improved because the crystallinity of the dielectric layer 22 was improved, and the residue of the tapered resist patterns 32 was removed by thermal decomposition. Further, by this heat treatment, the leak current flowing between the upper electrode 23 and the lower electrode 21 was reduced because the edge of the upper electrode 23 contracted.

Next, an inorganic protective layer 41 composed of silicon nitride, lead conductors 51a and 51b, an organic protective layer 42, and solder bumps 52a and 52b were deposited to complete the dielectric thin film capacitor shown in FIG. 9G.

In the dielectric thin film capacitor of the present example, the solder bumps 52a and 52b were connected to upper electrodes 23a and 23b, respectively, via the respective lead conductor 51a or 51b. This is an equivalent circuit in which two capacitors are connected in series. The method for manufacturing a dielectric thin film capacitor of the present example can produce the similar effect to that of EXAMPLE 1.

### Example 4

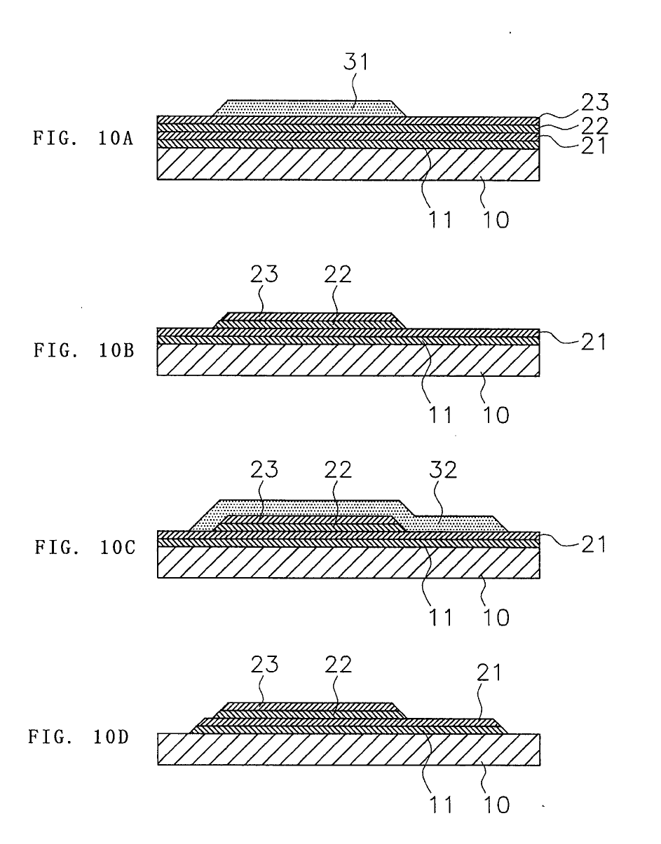

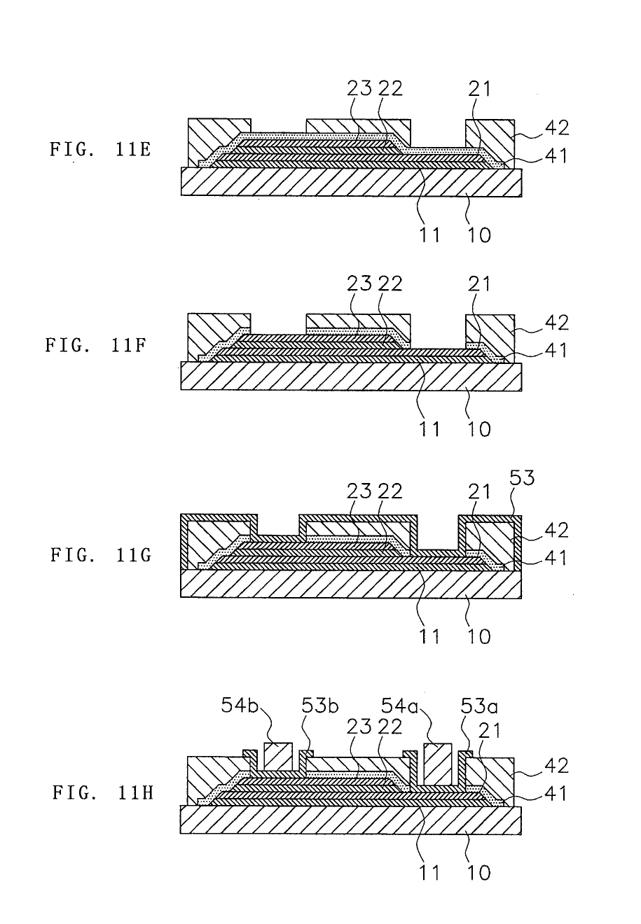

Next, EXAMPLE 4 of the present invention will be described with reference to FIGS. 10A to 11H. Note that, for the common part described in EXAMPLE 1, redundant description is avoided.

As shown in FIG. 10A, an adhesive layer 11, a lower electrode 21, a dielectric layer 22, and an upper electrode 23 were deposited on a substrate 10 using the same method as used in EXAMPLE 1 and a tapered resist pattern 31 was formed on an upper electrode 23. Further, parts of the dielectric layer 22 and the upper electrode 23 were removed as shown in FIG. 10B, by ion-milling using the tapered resist pattern 31 as a mask. Since the tapered resist pattern 31 was formed to have a tapered shape, the etched surfaces of the dielectric layer 22 and the upper electrode 23 were formed to have a tapered shape. That is, the etched surfaces of the dielectric layer 22 and the upper electrode 23 were inclined to the central portion in a direction away from the substrate 10.

Next, the tapered resist pattern 31 was removed by oxygen plasma ashing and then a tapered resist pattern 32 shown in FIG. 10C was formed using the same method as used for forming the tapered resist pattern 31.

Next, parts of the adhesive layer 11 and the lower electrode 21 were removed in one operation by ion-milling using a tapered resist pattern 32 as a mask. Then, the tapered resist pattern 32 was removed by oxygen plasma ashing. Consequently, as shown in FIG. 10D, the adhesive layer 11 and the lower electrode 21 were formed into a tapered shape. That is, the etched surfaces of the adhesive layer 11 and the lower electrode 21 were inclined to the central portion in a direction away from the substrate 10.

Next, heat treatment was performed for about 30 minutes at a temperature of about 850° C. in an oxidative atmosphere. By this heat treatment, the dielectric constant of the dielectric layer 22 was improved because the crystallinity of the dielectric layer 22 was improved, and the residue of the resist patterns 32 was removed by thermal decomposition. Further, by this heat treatment, the leak current flowing between the upper electrode 23 and the lower electrode 21 was reduced because the edge of the upper electrode 23 contracted.

Next, an inorganic protective layer 41 composed of silicon nitride was formed as shown in FIG. 11E, then an organic protective layer 42 made of photosensitive polyimide resin was formed.

Next, as shown in FIG. 11F, parts of the inorganic protective layer 41 were removed by reactive ion etching using the organic protective layer 42 as a mask. Consequently, parts of the top surfaces of the upper electrode 23 and the lower electrode 21 were exposed at the bottoms of openings provided in the inorganic protective layer 41 and the organic protective layer 42.

Next, a Ti layer as an adhesive layer having a thickness of about 100 nm (not shown) and a metallic protective layer 53 composed of Cu having a thickness of about 500 nm was formed by sputtering as shown in FIG. 11G.

Next, a Cu layer having a thickness of about 4 μm and a Au layer having a thickness of about 0.5 μm were deposited in that order by electrolytic plating after forming a resist pattern. By removing the resist pattern, terminal electrodes 54a and 54b having a Cu/Au two-layer structure were formed in the openings provided in the inorganic protective layer 41 and the organic protective layer 42. Then, the metallic protective layer 53 was patterned into divided layers, i.e., a metallic protective layer 53a and a metallic protective layer 53b, by photolithography so as to complete a dielectric thin film capacitor shown in FIG. 11H.

According to the present example, the following advantages as well as the similar effects to those in EXAMPLE 1 were provided.

First, reliability of the dielectric thin film capacitor can be improved by providing the thin metal protective layers 53a and 53b between the terminal electrode 54a and the lower electrode 21 and between the terminal electrode 54b and the upper electrode 23, respectively. This is because the thin metal protective layers can prevent the capacitor structure from being directly subjected to stress occurring in the terminal electrodes. Note that the terminal electrodes 54a and 54b need a sufficient thickness in order to secure the connection with an exterior device although the strength of a stress occurring in the terminal electrodes during a formation process is also increased in proportion to the thickness.

Second, the entire thickness of the dielectric thin film capacitor can be reduced because the lead conductors 54a and 54b, which are required to have a certain thickness or more, are disposed in the openings provided in the inorganic protective layer 41 and the organic protective layer 42.

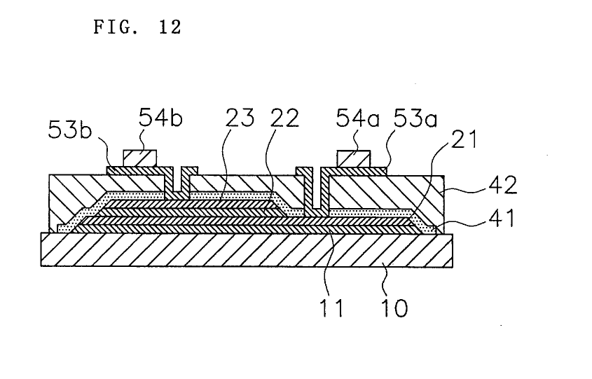

Also, as a modified example, a dielectric thin film capacitor shown in FIG. 12 can be manufactured. The dielectric thin film capacitor shown in FIG. 12 has metal protective layers 53a and 53b extending on the organic protective layer 42 and the terminal electrodes 54a and 54b formed on the metal protective layers 53a and 53b disposed on the organic protective layer 42.

Consequently, an impact given from the outside to the terminal electrodes 54a and 54b can be tempered by the organic protective layer 42 being elastic so as to prevent the capacitor structure from being damaged by the impact although the entire thickness of the dielectric thin film capacitor comes larger than that of the capacitor shown in FIG. 11H.

While preferred embodiments of the invention have been described above, it is to be understood that variations and modifications will be apparent to those skilled in the art without departing the scope and spirit of the invention. The scope of the invention, therefore, is to be determined solely by the following claims.

What is claimed is:

1. A method for manufacturing a dielectric thin film capacitor comprising:
disposing a lower electrode, a dielectric layer, and an upper electrode on a substrate in that order to form a capacitor structure in which the dielectric layer is held between the lower electrode and the upper electrode;
forming a resist pattern on the capacitor structure, the resist pattern having a side face that is inclined toward a center of the resist pattern from a surface thereof in contact with the capacitor structure;
removing parts of the capacitor structure by dry etching using the resist pattern as a mask so that at least a part of a side face of the capacitor structure is inclined toward a center of the capacitor structure from a surface thereof in contact with the substrate;
heating the capacitor structure in an oxidative atmosphere after removing the resist pattern; and
forming a protective layer covering at least a part of the capacitor structure.

2. The method for manufacturing a dielectric thin film capacitor according to claim 1, wherein the protective layer is composed of silicon nitride.

3. The method for manufacturing a dielectric thin film capacitor according to claim 1, wherein the upper electrode and the dielectric layer are partially removed in one operation in the step of removing parts of the capacitor structure.

4. The method for manufacturing a dielectric thin film capacitor according to claim 1, wherein the heat treatment temperature is 600° C. or higher.

5. The method for manufacturing a dielectric thin film capacitor according to claim 1, further comprising forming an adhesive layer on the substrate before disposing the lower electrode thereon.

6. The method for manufacturing a dielectric thin film capacitor according to claim 5, wherein parts of the adhesive layer are also removed during dry etching of the capacitor structure.

7. The method for manufacturing a dielectric thin film capacitor according to claim 1, wherein the heat treatment is conducted at a temperature sufficient to improve crystallinity of the dielectric layer.

8. The method for manufacturing a dielectric thin film capacitor according to claim 1, wherein the heat treatment is conducted at a temperature and time sufficient to thermally decompose the resist pattern.

9. The method for manufacturing a dielectric thin film capacitor according to claim 1, wherein the heat treatment is conducted at a temperature sufficient to cause an end portion of the upper electrode to have a rounded shape.
